(19) United States
(12) Patent Application Publication
(10) Pub. No.: US 2012/0236579 A1
(43) Pub. Date: Sep. 20, 2012

(54) FLEXIBLE WIRING MODULE AND FLEXIBLE WIRING DEVICE

(75) Inventors: Hiroshi Uemura, Yokohama-shi (JP); Hideto Furuyama, Yokohama-shi (JP)

(73) Assignee: KABUSHIKI KAISHA TOSHIBA, Tokyo (JP)

(21) Appl. No.: 13/369,425

(22) Filed: Feb. 9, 2012

(30) Foreign Application Priority Data
Mar. 16, 2011 (JP) 2011-058437

(51) Int. Cl. F21V 21/00; H05K 1/14; H05K 1/02

(52) U.S. Cl. 362/382; 174/254; 361/736

(57) ABSTRACT

According to one embodiment, a flexible wiring module includes a flexible wiring board including a plurality of electrical wirings, a through slit configured to divide the wiring board into a plurality of fins, and a bundling region configured to bundle the plurality of wiring fins. The through slit divides a wiring region of the wiring board into a plurality of wiring fins including a first wiring fin and a second wiring fin having electrical wiring width larger than that of the first wiring fin. The bundling region bundles a laminated portion having at least a portion of the wiring fins laminated in a thickness direction and bundles the fins to cause the second wiring fin to be arranged on at least one of the upper and lower layers of the first wiring fin.

### CROSS-REFERENCE TO RELATED APPLICATIONS

This application is based upon and claims the benefit of priority from prior Japanese Patent Application No. 2011-058437, filed Mar. 16, 2011, the entire contents of which are incorporated herein by reference.

### FIELD

Embodiments described herein relate generally to a flexible wiring module and flexible wiring device.

### BACKGROUND

As a wiring arranged on a mechanically movable portion and bent portion of an electronic device, a flexible wiring board with flexibility is used. With enhancement of the performance of an electronic device such as a bipolar transistor and field-effect transistor, an attempt is made to greatly increase the operating speed of a large-scale integrated circuit (LSI). Along with this, there occurs a problem that the speed limitation is imposed on an electrical wiring that connects LSIs and erroneous operation due to electromagnetic noise occurs. In order to cope with this problem, a flexible optical interconnection board on which a high-speed signal is transmitted via light is proposed.

### BRIEF DESCRIPTION OF THE DRAWINGS

FIG. 1 is a top view showing the schematic configuration of a flexible wiring module according to a first embodiment.

FIGS. 2A, 2B are schematic cross-sectional views taken along lines A-A′ and B-B′ of FIG. 1.

FIG. 3 is a top view showing the schematic configuration of a flexible wiring device according to a first embodiment.

FIGS. 4A to 4E are top views showing manufacturing steps of the flexible wiring module according to the first embodiment.

FIG. 5 is a cross-sectional view showing a modification of the flexible wiring module according to the first embodiment.

FIG. 6 is a top view showing the schematic configuration of a flexible wiring module according to a second embodiment.

FIGS. 7A, 7B are a top view and cross-sectional view showing the structure of a second wiring board used in the second embodiment.

FIGS. 8A, 8B are top views showing the structure of first and second wiring boards used in the second embodiment.

### DETAILED DESCRIPTION

According to one embodiment, a flexible wiring module includes a flexible wiring board including a plurality of electrical wirings, a through slit configured to divide the wiring board into a plurality of fins, and a bundling region configured to bundle the plurality of wiring fins. The wiring board includes a pair of end regions separated in a wiring lengthwise direction and a wiring region sandwiched between the end regions. The through slit divides the wiring region of the wiring board into a plurality of wiring fins including a first wiring fin and a second wiring fin having electrical wiring width larger than that of the first wiring fin. The bundling region bundles a laminated portion having at least a portion of the wiring fins laminated in a thickness direction and bundles the fins to cause the second wiring fin to be arranged on at least one of the upper and lower layers of the first wiring fin.

Next, this embodiment is explained with reference to the drawings. In this case, the explanation is made while some concrete materials and configurations are used as an example, but other materials and configurations having the same functions can be similarly used. Therefore, this invention is not limited to the following embodiments.

Further, in the following embodiments, only the substrate shape of the flexible wiring module may be shown and a wiring pattern such as an electrical wiring may be omitted in some cases. This is made to simplify the explanation and it is needless to say that a given wiring can be formed.

### First Embodiment

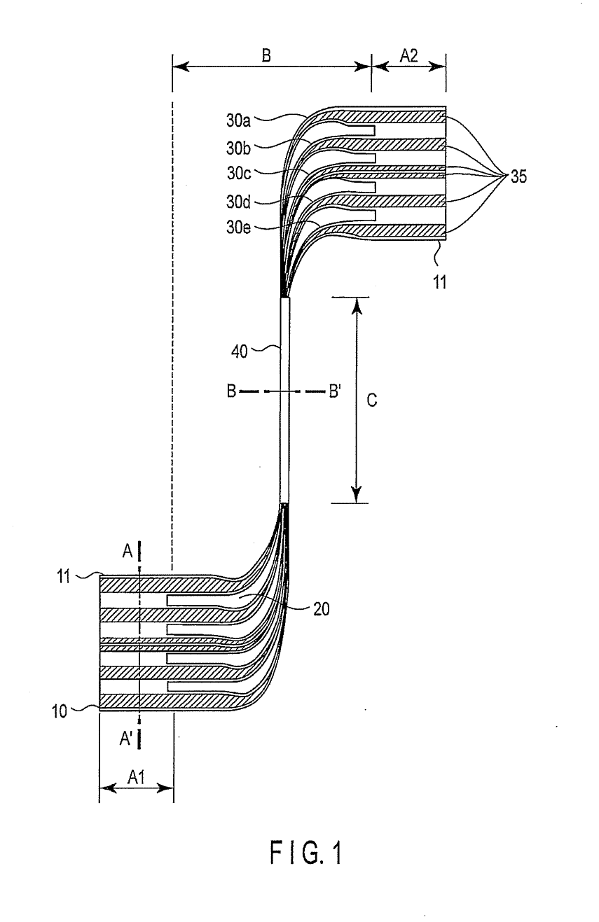

FIG. 1 is a top view showing the schematic configuration of a flexible wiring module according to a first embodiment.

In the flexible wiring module of this embodiment, a plurality of through slits 20 are provided in wiring region B except end regions 11 (A1, A2) of one flexible wiring board 10. Wiring region B of the wiring board 10 is divided into a plurality of wiring fins 30 (30a to 30e) by use of the through slits 20. The numbers of the slits 20 and wiring fins 30 are indicated only one example and are not limited to this case. The plurality of divided wiring fins 30 are bundled by a bundling band 40 in bundling region C lying in an intermediate portion of wiring region B.

Electrical wirings 35 extend from one end region A1 to the other end region A2 via wiring fins 30a to 30e. Bundling region C is a region having the wiring fins 30 bundled and forms a flexible wiring bundle that can be bent in both directions of a normal (perpendicular to the drawing sheet) direction to the plane of the end region 11 and a horizontal (parallel to the drawing sheet) direction.

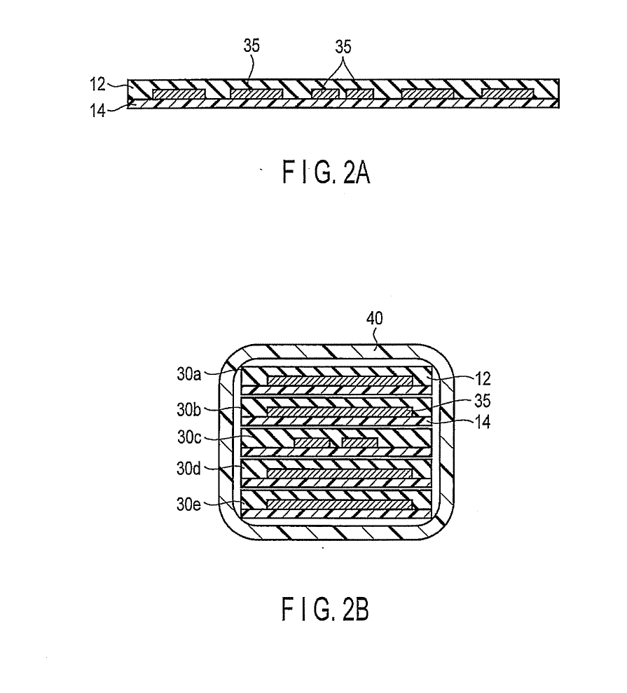

As a configuration example of the flexible wiring board 10 used in this embodiment, as shown in the cross-sectional view of FIG. 2A taken along line A-A′ of FIG. 1, for example, a laminated body with the three-layered structure having a base film 14 formed of a polyimide film with a thickness of 25 μm, an electrical wiring 35 formed of a rolled Cu foil with a thickness of 25 μm and a cover layer 12 formed of a polyimide film with a thickness of 25 μm is provided. The whole dimensions of the flexible wiring board are set to have the width of 10 mm and the length of 150 mm. Both end portions of 10 mm of the flexible wiring board 10 are left behind as end regions A1, A2 and slits 20 with the width of 0.1 mm are formed at a pitch of 1 mm by means of a laser cutter. As a result, 10 wiring fins 30 with the width of 0.9 mm and the length of 130 mm are formed.

The wiring fins 30 are used in a bundled form, and therefore, it is preferable to set the widths of all of the wiring fins 30 to substantially the same width. It is needless to say that an electrical wiring pattern of Cu or the like is not provided in a portion in which the through slits 20 are formed. Further, it is preferable to set the width of the wiring fin 30 to 1/10 of the wiring region length or less from the viewpoint of flexibility. These are also applied to the following embodiments.

Next, the wiring fin groups are sequentially laminated and collected in an arranged order and, for example, a fluorine resin-series seal tape is used as the bundling band 40 to bundle fins in at least a portion of wiring region B as shown in FIG. 1. It is preferable to set the length of bundling region C to 100 mm, for example, and arrange the same in substantially the central portion of wiring region B. At this time, a tape having no adhesive is used as the bundling band 40 and a non-fixed state is set to permit the wiring fin 30 to move inside the bundled band 40. As a result, the expansion and bending stress of the wiring fin 30 at the bending time of bundling region C can be easily alleviated and the flexibility of bundling region C can be greatly increased.

In the flexible wiring module of this embodiment, as shown in the cross-sectional view of FIG. 2B taken along line B-B′ of FIG. 1, second wiring fins 30b, 30d having electrical wirings 35 with larger width than that of an electrical wiring 35 of a first wiring fin 30c are arranged adjacent to the upper and lower layers of the first wiring fin 30c arranged inside bundling region C. Therefore, a three-layered electrical wiring structure (strip line structure) is formed of wiring fins 30b, 30c, 30d.

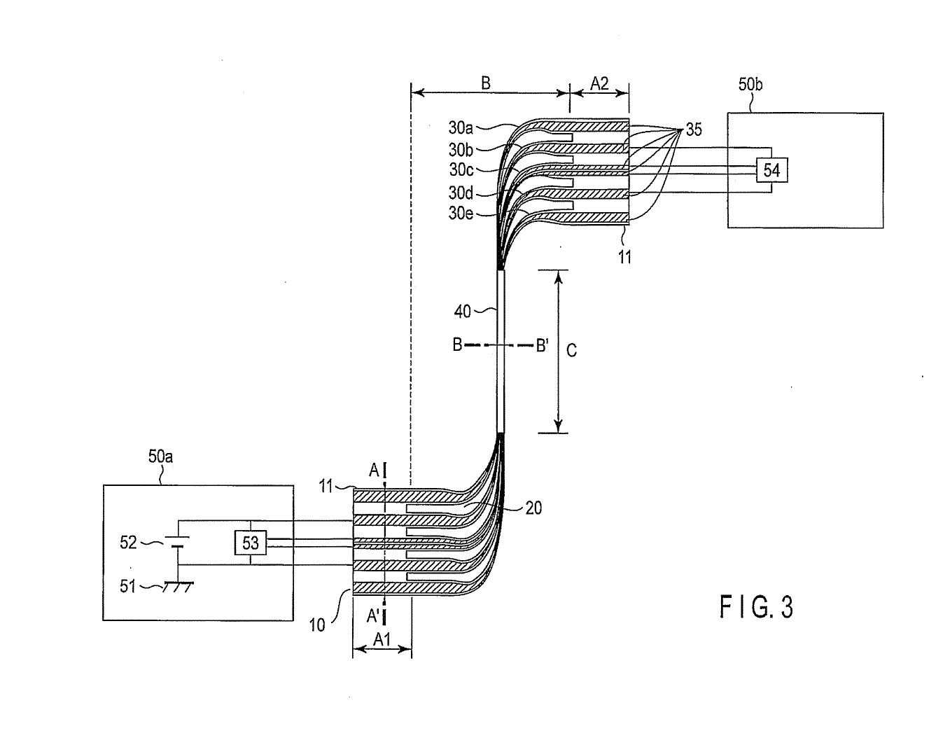

In a flexible wiring device configured by connecting two electrical circuits by use of the above flexible wiring module, the reliability can be enhanced. Specifically, as shown in FIG. 3, an electrical circuit 50a including, for example, a ground potential node 51, DC power source 52 and transmitter circuit 53 is connected to first electrical connection terminals (not shown) of the flexible wiring module on the side of end region A1. The electrical connection terminals can be formed by exposing portions of the electrical wirings 35 and plating Ni/Au (thickness 5 μm/0.3 μm), for example, on the surfaces thereof. On the side of end region A2, an electrical circuit 50b including, for example, a receiver circuit 54 is connected to second electrical connection terminals (not shown) of the flexible wiring module.

In the above flexible wiring device, the characteristic impedance of the electrical wiring 35 of the first wiring fin 30c can be easily controlled to a desired value by fixing the electrical wirings of the second wiring fins 30b, 30d at preset potentials.

For example, the characteristic impedance can be matched between the electrical wiring 35 of the first wiring fin 30c and the transmission line that connects the transmitter circuit 53 and the flexible wiring module. As a result, reflection of a high-speed signal at the connection node of the electrical wiring 35 and the transmission line on the transmitter circuit 53 side can be greatly reduced when a high-speed signal (for example, NRZ differential signal of 1 Gbps) output from the transmitter circuit 53 of the electrical circuit 50a is transmitted via the electrical wiring 35 of the first wiring fin 30c. Likewise, the characteristic impedance can be matched between the electrical wiring 35 of the first wiring fin 30c and a transmission line that connects the receiver circuit 54 and the flexible wiring module when a high-speed signal transmitted via the electrical wiring 35 of the first wiring fin 30c is received by the receiver circuit 54 of the electrical circuit 50b. Therefore, reflection of a high-speed signal at the connection node of the electrical wiring 35 and the transmission line on the receiver circuit 54 side can be greatly reduced. That is, the quality of signal transmission from the transmitter circuit 53 to the receiver circuit 54 can be greatly enhanced.

Further, since the electrical wirings 35 of the second wiring fins 30b, 30d function as shields, the following effect can be obtained. That is, electromagnetic noise generated from the electrical wiring 35 of the first wiring fin 30c by transmitting a high-speed signal can be prevented from being coupled with the electrical wirings 35 of wiring fins 30a, 30e that lie above and below the first wiring fin 30c or from being radiated to the exterior of the flexible wiring module. That is, occurrence of crosstalk or electromagnetic noise radiation can be suppressed. Further, in the flexible wiring module of this embodiment, as described before, the wiring fins 30 (including wiring fins 30b, 30d functioning as electromagnetic shields) are set in a non-fixed state to be movable in the bundling band 40. Therefore, the flexibility of bundling region C can be greatly increased.

As a general electromagnetic shield method, for example, a method for adhering a sheet containing a radio wave absorption material such as Fe, Ni, ferrite or the like to a flexible wiring board is provided. However, with this method, the wiring fin having the sheet containing the radio wave absorption material adhered thereto becomes thick and there occurs a possibility that the flexibility of the bundling region is greatly reduced. Further, at the bending time of the bundling region, compression strain is applied to one surface side of the wiring fin and tensile strain is applied to the other surface side as viewed from the center of the radius of curvature. Therefore, the sheet containing the radio wave absorption material may be separated from the wiring fin, leading to a lowering in the reliability.

Thus, according to this embodiment, the slits 20 are formed in the flexible wiring board 10 to divide wiring region B into a plurality of wiring fins 30 with substantially the same width and every adjacent wiring fins 30 are laminated in the non-fixed state and bundled and integrated by means of the bundling band 40. Further, the second wiring fins 30b, 30d having electrical wirings with width larger than that of the electrical wiring of the wiring fin 30c are arranged adjacent to the upper and lower layers of the first wiring fin 30c arranged inside. As a result, a flexible wiring module can be realized in which the quality of signal transmission can be enhanced and radiation of electromagnetic noise can be suppressed and that has excellent flexibility.

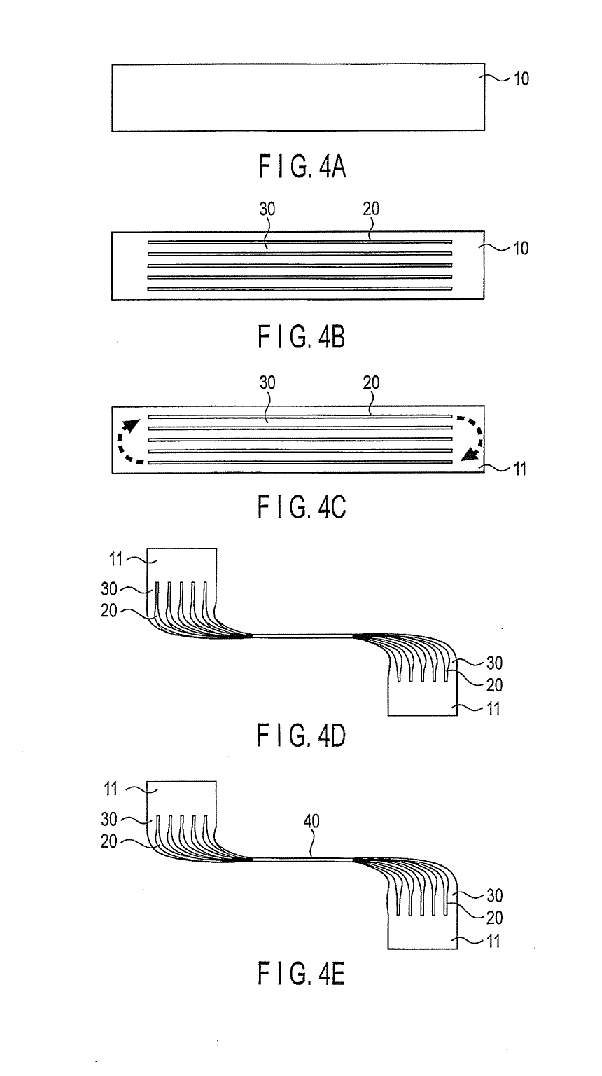

One example of the manufacturing process of the flexible wiring module shown in FIG. 1 is explained with reference to FIGS. 4A to 4E.

FIG. 4A shows a state in which a normal flexible wiring board manufacturing step is terminated and a stage in which wirings such as a Cu wiring pattern (not shown) have been formed. As described before, in this stage, no wirings are provided in a portion in which through slits are formed. FIG. 4B shows a step of forming a plurality of through slits 20 to form divided wiring fins 30. For formation of the through slits 20, router processing such as die punching or mechanical cutting can be used in addition to laser processing as described before.

Next, two end regions 11 are simultaneously rotated at two portions in an in-plane direction as indicated by arrows of broken lines shown in FIG. 4C. By this operation, the wiring fins 30 are twisted and get closer to one another. At this time, appropriate tensions are applied to the end regions 11 according to the rotated directions with the positions deviated as shown in FIG. 4D. As a result, the wiring fins 30 are overlapped with the front surface and back surface of the adjacent wiring fins 30 set to face each other, neatly arranged and formed into a bundle. With this state kept, a bundling band 40 is wound around the fins to complete a flexible wiring module as shown in FIG. 4E.

As the process for overlapping the wiring fins 30, a different method can be used. For example, a plurality of wiring fins may be overlapped with the front surfaces or back surfaces of the adjacent wiring fins set to face each other.

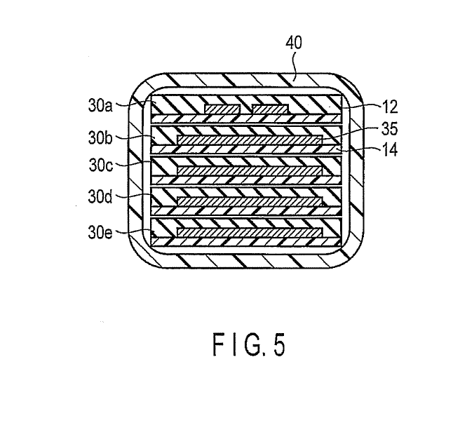

The first wiring fin may be provided in any position inside bundling region C or the first wiring fin may be provided on the outermost layer as shown in FIG. 5. In the case of FIG. 5, 30a corresponds to the first wiring fin and 30b corresponds to the second wiring fin. If the first wiring fin is provided on the outermost layer, the second wiring fin can be arranged only on one of the upper and lower layers of the first wiring fin. However, an electrical wiring of the first wiring fin 30a and an electrical wiring of the second wiring fin 30b adjacent thereto can be combined to form a microstrip line structure.

As a result, the characteristic impedance of the electrical wiring of the first wiring fin 30a can be easily controlled by connecting an electrical circuit to the flexible wiring module and fixing the electrical wiring of the second wiring fin 30b at preset potential. Therefore, the effect described before can be achieved. Further, at this time, since electromagnetic coupling can be attained between the electrical wiring of the first wiring fin 30a and the second wiring fin 30b, electromagnetic noise radiation to outside the flexible wiring module can be greatly suppressed.

Likewise, the second wiring fin may be arranged adjacent to only one of the upper and lower layers of the first wiring fin when the first wiring fin is provided inside the layer.

The second wiring fin may not be arranged adjacent to the first wiring fin and can be arranged on the outermost layer in the bundling region (for example, 30a, 30e in FIG. 2B). In this case, if an electrical circuit is connected to the flexible wiring module and the electrical wirings of the second wiring fins 30a, 30e are fixed at preset potentials, the second wiring fins 30a, 30e can be formed to function as electromagnetic shields. Then, electromagnetic noises generated from electrical wirings of the first wiring 30c and other wiring fins (for example, 30b, 30d in FIG. 2B) can be prevented from being radiated to the outside of the flexible wiring module and electromagnetic noise radiation can be suppressed.

In FIG. 2B, the number of electrical wirings of the first wiring fin is set to two but may be set to one or three or more. If a plurality of electrical wirings are used, it becomes possible to transmit a large number of signals and supply multi-series power source voltages. Further, the electrical wiring of the first wiring fin may be differential signal wirings configured to transmit information by two electrical signals with a phase difference of 180 degrees or may be a single-end wiring configured to transmit information by use of one electrical signal. Likewise, a plurality of second electrical wirings can be used. If a plurality of electrical wirings of the first wiring fin are used and a plurality of electrical wirings of the second wiring fin are used, the width of one of the electrical wirings of the first wiring fin is compared with the width of one of the electrical wirings of the second wiring fin and it is satisfactory if the width of the electrical wiring of the second wiring fin is larger.

It is preferable to arrange the second wiring fin and the electrical wiring of the second wiring fin to cover portions lying above or below the electrical wiring of the first wiring fin. As a result, electromagnetic noises generated from the electrical wiring of the first wiring and the electrical wirings of other wiring fins can be prevented from being leaked to the exterior of the flexible wiring module. That is, electromagnetic noise radiation can be more effectively suppressed.

In FIG. 3, the circuit in which the transmitter circuit 53 and receiver circuit 54 are supplied with power from the DC power source 52 of the electrical circuit 50a is shown, but the circuits may be supplied with power from another DC power source.

In FIG. 3, the electrical wirings of the outermost wiring fins 30a, 30e in bundling region C are not connected to the electrical circuit 50 and are made to float. However, this case is not limited to this example and they may be set to power source wirings (preset potentials) or may be used for signal transmission.

### Second Embodiment

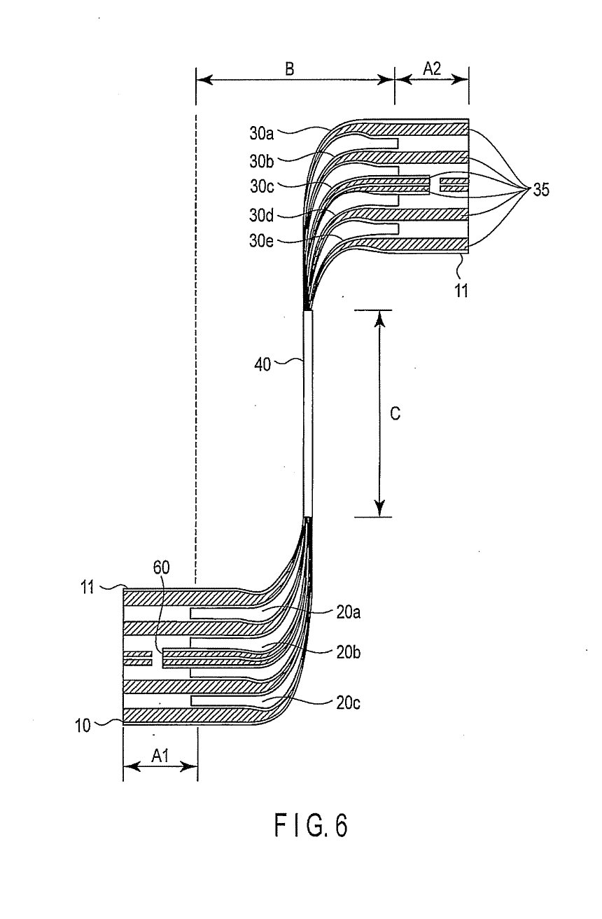

FIG. 6 is a top view showing the schematic configuration of a flexible wiring module according to a second embodiment. Portions that are the same as those of FIG. 1 are denoted by the same symbols and the detailed explanation thereof is omitted.

In the first embodiment, the flexible wiring module is formed by processing one flexible wiring board. A flexible wiring module of this embodiment is formed by integrating a plurality of flexible wiring boards individually formed.

A flexible wiring module shown in FIG. 6 includes a flexible wiring board 10 having through slits 20 (20a to 20c) formed therein and a different flexible wiring board 60 mounted on the through slit 20b of the board 10. By bonding and fixing the flexible wiring board 60, the flexible wiring boards 10 and 60 are integrated. The width of the through slit 20b is larger than that of the through slits 20a, 20c and is larger than the width of wiring board 60. The flexible wiring board 60 and flexible wiring board 10 are bonded to and fixed on each other in each of end regions A1, A2 of the flexible wiring board 10. For bonding and fixing, for example, thermosetting epoxy-series resin or double-sided adhesive sheet can be used.

Further, the electrical wirings of the flexible wiring board 60 and the electrical wirings of the flexible wiring board 10 are electrically connected via electrical connection terminals (not shown) that are adequately formed. For electrical connection, for example, wire bonding, ink jet wiring, anisotropic conductive film (ACF) or anisotropic conductive paste (ACP) can be used. Thus, input/output terminals of all of the electrical wirings of the wiring fins can be formed on the flexible wiring board 10.

Like the flexible wiring module of the first embodiment, in the thus formed flexible wiring module, the wiring fin groups can sequentially be laminated and collected in an arranged order to form bundling region C. In bundling region C, the wiring fin 30 and wiring board 60 are set in a non-fixed state to be movable, and therefore, expansion and bending stress of the wiring fin 30 at the bending time of bundling region C can be easily reduced and the flexibility of bundling region C can be greatly enhanced.

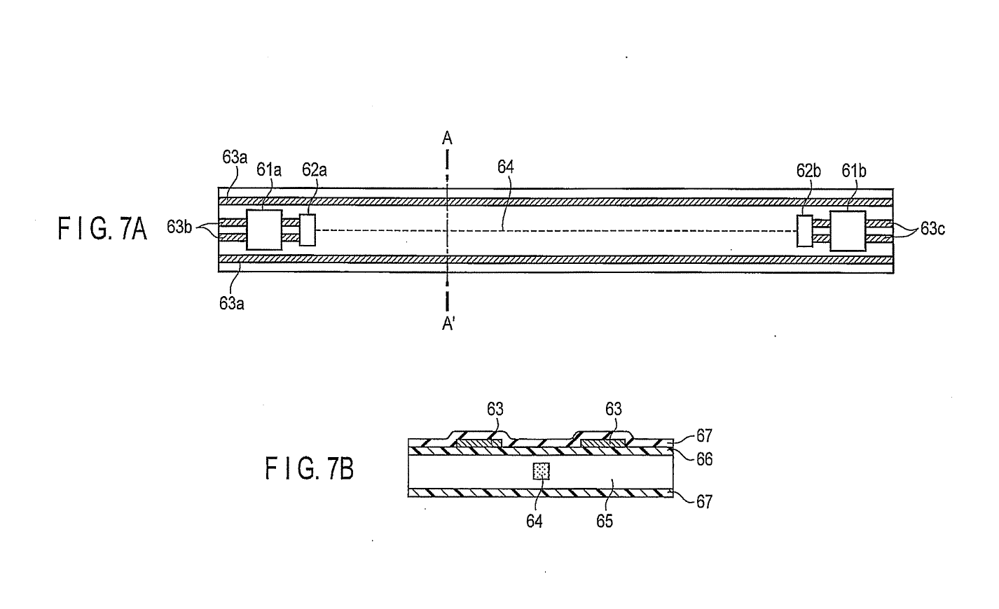

FIG. 7A is a schematic top view of the flexible wiring board 60 and FIG. 7B is a schematic cross-sectional view of the flexible wiring board 60 taken along line A-A′ of FIG. 7A.

The flexible wiring board 60 includes electrical wirings 63 (63a to 63c) and optical interconnection path 64. Further, on the flexible wiring board 60, optical semiconductor elements 62 (a light emitting element 62a that converts an electrical signal to an optical signal and a light receiving element 62b that converts an optical signal to an electrical signal) and drive ICs 61 (a drive IC 61a that drives the light emitting element 62a and a drive IC 61b that drives the light receiving element 62b to amplify a received current) are mounted. The drive IC 61 and optical semiconductor element 62 are mounted in a flip-chip fashion on the flexible wiring board 60 and electrically connected to electrical wirings 63 via Au stud bumps, for example. Further, the optical semiconductor elements 62a, 62b are optically coupled via the optical interconnection path 64.

For example, the electrical wiring 63 is formed of a rolled Cu film with a thickness of 12 μm, for example, on a base film 66 formed of a polyimide film with a thickness of 20 μm, for example. Further, the surface thereof is covered with a cover layer 67 formed of a polyimide film with a thickness of 25 μm, for example, except the electrical connection terminals (not shown) and mounting portions of the optical semiconductor elements 62 and drive ICs 61. The electrical connection terminal can be formed by plating, for example, Ni/Au (thickness: 5 μm/0.3 μm) on the surface of the electrical wiring 63.

An optical interconnection layer is formed under the base film 66. The optical interconnection path (optical waveguide core) 64 is formed of epoxy-series resin with the cross section of 30 μm×30 μm and the surroundings are configured to be covered with an optical waveguide clad 65 (for example, epoxy-series resin with a thickness of 50 μm) used for optical confinement. A cover layer 67 formed of a polyimide film with a thickness of 25 μm, for example, is formed below the optical interconnection layer.

As an optical waveguide material (optical waveguide core 64 and optical waveguide clad 65), for example, acrylic-series resin, polyimide-series resin or the like can be used in addition to epoxy-series resin. However, the material and additive that are properly adjusted are used to make the refractive index of the optical waveguide core 64 higher than that of the optical waveguide clad 65. Further, the optical coupling of the optical waveguide core 64 with the optical semiconductor elements 62 can be realized by previously providing a 45° mirror (not shown) on the optical waveguide core 64 in the mounting position of the optical semiconductor elements, for example.

In the flexible wiring board 60, the drive IC 61a drives the light emitting element 62a based on an electrical signal input to the electrical wiring 63b to generate an optical signal and the optical signal is transmitted via the optical interconnection path 64. Next, an optical signal received by the light receiving element 62b is converted to an electrical signal, amplified by the drive IC 61b and output to the electrical wiring 63c. Further, the drive Ics 61a, 61b are supplied with power source voltages via the electrical wiring 63a.

By using the above flexible wiring board 60, extremely high-speed signal transmission (for example, 10 Gbps) in comparison with a case wherein the electrical wiring is used can be achieved in the flexible wiring module of this embodiment. Further, the normal flexible wiring board 10 can be used for low-speed signal transmission (for example, 10 Mbps or less) or power supply. Therefore, the flexible wiring board 60 is used in a minimum sufficient region and integrally formed with the flexible wiring board 10. As a result, the rise of the cost of the wiring members can be greatly suppressed in comparison with the configuration in which all of the signal wirings are provided by use of the flexible wiring board 60.

Further, when high-speed transmission is performed by use of the flexible wiring board 60, no electromagnetic noise is generated from the optical interconnection path, but when the optical semiconductor element 62 is driven, electromagnetic noise generated from the drive IC 61 tends to be coupled with the electrical wiring 63a directly connected to the drive IC 61. Therefore, the flexible wiring board 60 is used as a first wiring fin (30c in FIG. 2B) and 30b, 30d adjacent to the first wiring fin 30c are used as second wiring fins. Further, an electrical circuit is connected to the flexible wiring module to fix the electrical wirings of the second wiring fins 30b, 30d at preset potentials. As a result, electromagnetic noise coupled with the electrical wiring 63a can be suppressed from being coupled with the electrical wirings of wiring fins 30a, 30e or from being radiated to the exterior.

Thus, in this embodiment, an excellent flexible wiring module can be provided in which the rise of the cost of the wiring members for high-speed signal transmission can be greatly suppressed, the signal transmission quality can be enhanced and electromagnetic noise radiation can be suppressed and that has flexibility.

In the flexible wiring module shown in FIG. 6, it is preferable to design the widths of the through slits 20 and flexible wiring board 60 to set the widths of all of the wiring fins 30 and the distance between the wiring fins to approximately the same values. For example, the widths of all of the wiring fins are set to 1 mm and the widths of all of the through slits are set to 0.1 mm by setting the width of the flexible wiring board 10 to 5.4 mm, setting the widths of the through slits 20a, 20c to 0.1 mm, setting the width of the through slit 20b to 1.2 mm and setting the width of the flexible wiring board 60 to 1 mm.

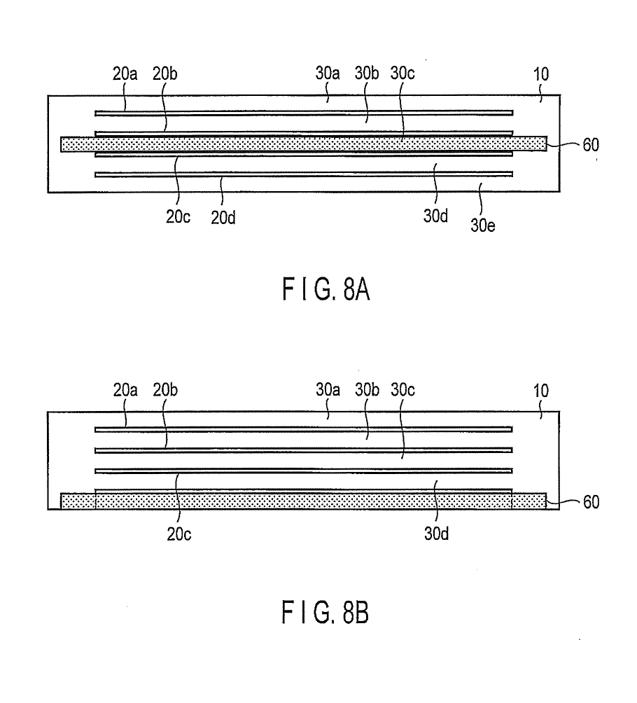

In FIG. 6, an example in which the flexible wiring board 60 is mounted on the through slit 20b with large width is shown, but this embodiment is not necessarily limited to this example. As shown in FIG. 8A, the flexible wiring board 60 may be mounted on any one of the wiring fins of the flexible wiring board 10 (for example, wiring fin 30c). Further, as shown in FIG. 8B, it may be mounted outside wiring fins 30a to 30d of the flexible wiring board 10. In FIG. 8B, the flexible wiring board 10 is divided to four wiring fins 30a to 30d by use of three through slits 20a to 20c and the end regions lying on both of the end portions thereof are formed to extend to the exterior (lower portion in FIG. 8B) of wiring fin 30d. The flexible wiring board 60 is adhered to and fixed on the extending portions in the end regions of the flexible wiring board 10.

Like the first embodiment, also, in this embodiment, the second wiring fin is not arranged adjacent to the first wiring fin and can be arranged on the outermost layer of the bundling region. Electromagnetic noise generated from electrical wirings of the first wiring fin and other wiring fins can be prevented from being radiated to the exterior of the flexible wiring module by connecting the electrical circuit to the flexible wiring module and fixing the electrical wiring of the second wiring fin at preset potential.

The flexible wiring board 60 is not necessarily a flexible wiring board capable of performing optical signal transmission and may be a flexible wiring board using a material with a low dielectric constant (for example, liquid crystal polymer [LCP]) as a base film. In such a flexible wiring board, signal transmission of high speed to some extent (for example, 1 Gbps) can be achieved without using optical signal transmission since the capacitance of the electrical wiring can be reduced. At this time, the cost of the members is increased in comparison with a flexible wiring board using polyimide that is a general material as a base film. However, the rise of the cost of the wiring members used for high-speed signal transmission can be suppressed by integrating the flexible wiring board with the minimum sufficient region with a general flexible wiring board as in this embodiment.

### Third Embodiment

In the first and second embodiments, the flexible wiring module in which the width of the electrical wiring of the second wiring fin is larger than the width of the electrical wiring of the first wiring fin is used. However, in this embodiment, a flexible wiring module in which the limitation imposed on the width of an electrical wiring of a wiring fin is eliminated by connecting an electrical circuit to the flexible wiring module can be used.

Like the flexible wiring device shown in FIG. 3, for example, an electrical circuit 50a including a ground potential node 51, DC power source 52 and transmitter circuit 53 is connected to electrical connection terminals (not shown) of the flexible wiring module on the end region A1 side of the flexible wiring module. Further, on the end region A2 side, for example, an electrical circuit 50b including a receiver circuit 54 is connected to electrical connection terminals (not shown) of the flexible wiring module. The electrical wirings of wiring fins 30b, 30d are fixed at present potentials.

As a result, the electrical wirings of wiring fins 30b, 30d function as electromagnetic shields. Therefore, when a high-speed signal output from the transmitter circuit 53 of the electrical circuit 50a is transmitted via the electrical wiring of wiring fin 30c, electromagnetic noise generated from the electrical wiring of wiring fin 30c can be prevented from being coupled with wiring fins 30a, 30e that lie above and below wiring fin 30c or from being radiated to the exterior of the flexible wiring module. Thus, crosstalk or electromagnetic noise radiation can be greatly suppressed.

As described above, according to this embodiment, an excellent flexible wiring device can be provided in which electromagnetic noise radiation can be suppressed and that has flexibility.

In the flexible wiring device of this embodiment, the flexible wiring module of the first or second embodiment may be used or a flexible wiring module in which the width of the electrical wiring of the second wiring fin is smaller than the width of the electrical wiring of the first wiring fin may be used in the flexible wiring module explained in the first or second embodiment. In the latter case, the effect for more effectively suppressing crosstalk and electromagnetic noise radiation in comparison with a case wherein the second wiring fin is not provided can be achieved.

The first wiring fin may include one or a plurality of electrical wirings. Further, the electrical wiring in the first wiring fin may be differential signal wirings configured to transmit information by use of two electrical signals with a phase difference of 180 degrees or may be a single-end wiring configured to transmit information by use of one electrical signal. Likewise, the second wiring fin may include one or a plurality of electrical wirings. Further, the electrical wiring of the second wiring fin may be configured by a plurality of electrical wirings whose widths are each smaller than that of the electrical wiring of the first wiring fin.

The first wiring fin may be arranged in any position inside the bundling region and may be arranged on the outermost layer. When the first wiring fin is arranged on the outermost layer, the wiring fin functioning as an electromagnetic shield is arranged only on the upper or lower layer thereof. Even in this case, electromagnetic noise radiation can be suppressed in a portion above or below the first wiring fin. Likewise, the second wiring fin may be arranged in any position inside the bundling region and may be arranged on the outermost layer. When the first wiring fin is arranged inside the bundling region, the second wiring fin functioning may be arranged only on one of the upper and lower layers of the first wiring fin.

### Modification

This invention is not limited to the above embodiments. The dimensions (length and width), material and the like of the flexible wiring board may be adequately determined according to the specification. Likewise, the relationship between the end regions, wiring region and bundling region may be adequately determined according to the specification. Further, the number of wiring fins, that is, the number of through slits formed in the wiring board is not limited to the above case and the effect of this invention can be expected even if only one slit is provided.

It is most preferable to provide through slits to cause a plurality of wiring fins to have substantially the same width, but this is not necessarily limited to this case and a slight difference may be set within a permissible range.

In the flexible wiring board of this invention, an FPC (Flexible Printed Circuit) or FFC (Flexible Flat Cable) can be used. The electrical wirings of the FPC and FFC may be formed in a single-layered form or multi-layered form. As the light emitting element that is an optical semiconductor element, various light emitting elements such as a surface light emitting laser (VCSEL: Vertical Cavity Surface Emitting Laser), light emitting diode and semiconductor laser can be used. As the light receiving element that is an optical semiconductor element, various light receiving elements such as a PIN photodiode, MSM photodiode, avalanche photodiode and photoconductor can be used. The wavelength used for optical signal transmission may be adequately determined according to the dependency of loss of the optical interconnection path on the wavelength, for example. Further, the material of the optical semiconductor element may be adequately determined based on the light-emitting wavelength and light-receiving wavelength.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A flexible wiring module comprising:
a flexible wiring board configured to include a plurality of electrical wirings and electrical connection terminals for connecting the electrical wirings to an exterior, the wiring board including a pair of end regions separated in a wiring lengthwise direction and a wiring region sandwiched between the end regions,
at least one through slit formed to the wiring region to connect the end regions, the wiring region being, divided by means of the through slit into a plurality of wiring fins including a first wiring fin and a second wiring fin having width of the electrical wiring larger than that of the first wiring fin, and
a bundling region configured to bundle a laminated portion formed by laminating at least a portion of the wiring fins in a thickness direction of the wiring fin, the second wiring fin being arranged on at least one of the upper and lower layers of the first wiring fin in the bundling region.

2. The module of claim 1, wherein the second wiring fin is arranged adjacent to the first wiring fin.

3. The module of claim 1, wherein the second wiring fin is arranged on at least one of the outermost layers of the bundling region.

4. The module of claim 1, wherein the wiring fins are bundled in a non-fixed state in the bundling region.

5. A flexible wiring module comprising:
a first flexible wiring board configured to include a plurality of electrical wirings and first electrical connection terminals for electrically connecting the electrical wirings to an exterior, the first wiring board including a pair of end regions separated in a wiring lengthwise direction and a wiring region sandwiched between the end regions,
a second flexible wiring board configured to include an electrical wiring and a second electrical connection terminal for electrically connecting the electrical wiring to an exterior, the second wiring board being mounted on the first wiring board,
at least one through slit formed to the wiring region of the first wiring board to connect the end regions, the wiring region being divided into a plurality of wiring fins by means of the through slit, and
a bundling region configured to bundle a laminated body formed by laminating the second wiring board and at least a portion of the wiring fins in a thickness direction of the wiring fin, an wiring fin that has an electrical wiring whose width is larger than that of the electrical wiring of the second wiring board being arranged on at least one of the upper and lower layers of the second wiring board in the bundling region.

6. The module of claim 5, wherein the wiring fin is arranged adjacent to the second wiring board.

7. The module of claim 5, wherein the second wiring fin is arranged on at least one of the outermost layers of the bundling region.

8. The module of claim 5, wherein the second wiring board includes an optical interconnection path in addition to the electrical wiring.

9. The module of claim 8, wherein the second wiring board includes a light emitting element and drive IC on one end side of the optical interconnection path and a light receiving element and drive IC on the other end side thereof.

10. The module of claim 5, wherein the wiring fins and the second wiring board are bundled in a non-fixed state in the bundling region.

11. A flexible wiring device comprising:
a first flexible wiring board configured to include a plurality of electrical wirings and first electrical connection terminals for electrically connecting the electrical wirings to an exterior, the first wiring board including a pair of end regions separated in a wiring lengthwise direction and a wiring region sandwiched between the end regions,
at least one through slit formed to the wiring region to connect the end regions, the wiring region being divided into a plurality of wiring fins by means of the through slit,
a bundling region configured to bundle a laminated body formed by laminating at least a portion of the wiring fins in a thickness direction of the wiring fin, and
an electrical circuit connected to the electrical connection terminals of the wiring board, the electrical circuit applying a preset DC potential to the electrical wiring of one of the wiring fins.

12. The device of claim 11, wherein the wiring region is divided into a plurality of wiring fins including a first wiring fin and a second wiring fin having width of the electrical wiring larger than that of the first wiring fin, the second wiring fin is arranged on at least one of the upper and lower layers of the first wiring fin and a preset DC potential is applied to the electrical wiring of the second wiring fin.

13. The device of claim 12, wherein the second wiring fin is arranged adjacent to the first wiring fin.

14. The device of claim 12, wherein the second wiring fin is arranged on at least one of the outermost layers of the bundling region.

15. The device of claim 11, wherein the wiring fins are bundled in a non-fixed state in the bundling region.

16. The device of claim 11, further comprising a second flexible wiring board configured to include an electrical wiring and a second electrical connection terminal for electrically connecting the electrical wiring to an exterior, the second wiring board being mounted on the first wiring board and being laminated together with the wiring fins.

17. The device of claim 16, wherein the wiring fin including an electrical wiring whose width is larger than that of the electrical wiring of the second wiring board is arranged on at least one of the upper and lower layers of the second wiring board and a DC potential is applied to the electrical wiring of the wiring fin including the electrical wiring whose width is larger than that of the electrical wiring of the second wiring board.

18. The device of claim 16, wherein the wiring fins and the second wiring board are bundled in a non-fixed state in the bundling region.

19. The device of claim 16, wherein the second wiring board includes an optical interconnection path in addition to the electrical wiring.

20. The device of claim 19, wherein the second wiring board includes a light emitting element and drive IC on one end side of the optical interconnection path and a light receiving element and drive IC on the other end side thereof.
